(19) United States
(12) Patent Application Publication
(10) Pub. No.: US 2024/0039242 A1
(43) Pub. Date: Feb. 1, 2024

(54) Wavelength Tunable Laser

(71) Applicant: Nippon Telegraph and Telephone Corporation, Tokyo (JP)

(72) Inventors: Takuma Tsurugaya, Tokyo (JP); Shinji Matsuo, Tokyo (JP); Toru Segawa, Tokyo (JP); Takuma Aihara, Tokyo (JP)

(21) Appl. No.: 18/254,902

(22) PCT Filed: Dec. 22, 2020
(86) PCT No.: PCT/JP2020/047874

§ 371 Date: May 30, 2023

(51) Int. Cl. H01S 5/12; H01S 5/125; H01S 5/065; H01S 5/0687

(52) U.S. Cl. CPC H01S 5/1243; H01S 5/125; H01S 5/0654; H01S 5/0687

(57) ABSTRACT

A wavelength-tunable laser a circling waveguide having a circling structure; a first coupled waveguide coupled to the circling waveguide in one region; and a second coupled waveguide coupled to the circling waveguide in another region, wherein a first reflection region is connected in the light guiding direction of the first coupled waveguide, an active region and a second reflection region are sequentially connected in the light guiding direction of the second coupled waveguide, and the refractive index of at least part of the circling waveguide is modulated.

### CROSS-REFERENCE TO RELATED APPLICATIONS

This application is a national phase entry of PCT Application No. PCT/JP2020/047874, filed on Dec. 22, 2020, which application is hereby incorporated herein by reference.

### TECHNICAL FIELD

The present invention relates to a wavelength-tunable laser that includes a micro-ring resonator and a distributed Bragg reflector.

### BACKGROUND

A tunable laser diode (TLD) that is a laser diode whose lasing wavelength can be tuned with an external control signal is a necessary component in information transmission using a wavelength division multiplexing (WDM). Normally, a TLD has a terminal for controlling the lasing wavelength, in addition to a terminal for injecting current into the active region. Taking advantage of changes caused in the refractive index of a waveguide by heating or carrier injection, the TLD can control the lasing wavelength.

The most basic configuration of a TLD is a configuration called a two-electrode DBR-TLD that is formed with an active region and a distributed Bragg reflector (DBR) having an electrode for refractive index modulation. In addition to this, a three-electrode DBR-TLD including an electrode for phase adjustment is also widely known. In these DBR-TLDs, the refractive index of the DBR region is modulated by carrier injection, resistive heating, or the like, and the Bragg wavelength of the DBR is changed to sweep the stopband position. As a result, the longitudinal mode in which the threshold gain is minimized, which is the lasing mode, is swept while being dragged by the stopband, and thus, lasing wavelength tunability is achieved.

Other types of TLDs include: (1) one in which two filters with slightly different resonator free spectral ranges (FSRs) are combined, and a vernier effect between the two filters is used to enable lasing wavelength changes to occur over a very wide range (Non Patent Literature 1); (2) one in which distributed feedback (DFB) LDs with different lasing wavelengths are arranged in an array, and the operating temperature is then adjusted to finely adjust the lasing wavelength of each LD and cover a wide region (Non Patent Literature 2); and (3) one in which active regions and refractive-index control regions are alternately arranged in a DFB-LD, to automatically satisfy phase conditions and enable mode-hop-free tuning (Non Patent Literature 3).

As compared with a DBR-TLD, the above type (1) excels in the wavelength-tunable region, but requires two filters and complicated phase adjustment. Therefore, for ease of control, a DBR-TLD is preferable. In the above type (2), the LDs do not have any terminal for controlling the lasing wavelength and it is necessary to heat the LDs in each active region. Therefore, a DBR-TLD is preferable in terms of separation of the active regions from the heat sources. The above type (3) has remarkable features, requiring no phase adjustment and being mode hop free. However, it is necessary to design a precise resonator, and manufacture a complicated structure in which active regions and refractive-index control regions are alternately arranged. Therefore, a DBR-TLD is preferable in terms of ease of implementation.

### CITATION LIST

### Non Patent Literature

Non Patent Literature 1: T. Segawa, S. Matsuo, T. Kakitsuka, T. Sato, Y. Kondo, and R. Takahashi, “Semiconductor Double-Ring-Resonator-Coupled Tunable Laser for Wavelength Routing”, in IEEE Journal of Quantum Electronics, vol. 45, no. 7, pp. 892-899, 2009.

Non Patent Literature 2: H. Ishii, K. Kasaya, and H. Oohashi, “Spectral Linewidth Reduction in Widely Wavelength Tunable DFB Laser Array”, in IEEE Journal of Selected Topics in Quantum Electronics, vol. 15, no. 3, pp. 514-520, 2009.

Non Patent Literature 3: N. Nunoya, H. Ishii, Y. Kawaguchi, R. Iga, T. Sato, N. Fujiwara, and H. Oohashi, “Tunable Distributed Amplification (TDA-) DFB Laser with Asymmetric Structure”, IEEE J. Sel. Top.in Quantum Electron., Vol.17, No.6, pp. 1505-1512, 2011.

Non Patent Literature 4: N. Fujiwara, T. Kakitsuka, M. Ishikawa, F. Kano, H. Okamoto, Y. Kawaguchi, Y. Kondo, Y. Yoshikuni, and Y. Tohmori, “Inherently mode-hop-free distributed Bragg reflector (DBR) laser array”, in IEEE Journal of Selected Topics in Quantum Electronics, vol. 9, no. 5, pp. 1132-1137, 2003.

Non Patent Literature 5: H. Arimoto, T. Kitatani, T. Tsuchiya, K. Shinoda, A. Takei, H. Uchiyama, M. Aoki, and S. Tsuji., “Wavelength-Tunable Short-Cavity DBR Laser Array With Active Distributed Bragg Reflector”, in Journal of Lightwave Technology, vol. 24, no. 11, pp. 4366-4371, 2006.

### SUMMARY

### Technical Problem

To obtain single-mode characteristics, a DBR-LD normally needs to satisfy the condition: the stopband width of the DBR is equal to or smaller than the free spectral range (FSR) of the resonator. In a case where this condition is not satisfied, a plurality of longitudinal modes exists in the stopband of the DBR, and the plurality of longitudinal modes have similar threshold gains. Therefore, problems such as multimode lasing and frequent mode hopping occur. To ensure a sufficient reflectance while keeping the stopband width small in the DBR, the length L_{DBR} of the entire DBR (hereinafter referred to as the DBR length) needs to be set to a long length, after the coupling constant x (the constant indicating the intensity of the periodic refractive index modulation for causing Bragg reflection) is made smaller.

In the DBR-TLD at this point, it is necessary to uniformly modulate the refractive index of the entire DBR region, and carrier injection and resistive heating are performed on the entire region. This means that the power required for the refractive index modulation increases in proportion to the DBR length, and its power consumption can be a major problem in short-distance communication applications in which low-power characteristics are required.

In Non Patent Literature 4 as a specific example, the active region length is 50 μm, the front DBR length is 200 μm, the rear DBR length is 450 μm, and a current of 100 mA in total is injected into the DBR region to obtain a wavelength shift of 4.5 nm. Also, in Non Patent Literature 5, the active region length is 35 μm, the front DBR length is 200 μm, the rear DBR length is 300 μm, and a current of 150 mA in total is injected into the DBR region to obtain a wavelength shift of 4.8 nm. These current amounts are larger than the injected current amount required for an active region having a length of several tens of μm, and account for most of the total power consumption of a TLD. This is a bottleneck in lowering power consumption.

Solution to Problem

To solve the above problem, a wavelength-tunable laser according to embodiments of the present invention includes: a circling waveguide having a circling structure; a first coupled waveguide coupled to the circling waveguide in one region; and a second coupled waveguide coupled to the circling waveguide in another region. In the wavelength-tunable laser, a first reflection region is connected in the light guiding direction of the first coupled waveguide, an active region and a second reflection region are sequentially connected in the light guiding direction of the second coupled waveguide, and the refractive index of at least part of the circling waveguide is modulated.

Also, a wavelength-tunable laser according to embodiments of the present invention includes: a circling waveguide; a Y-branched coupled waveguide; and an active region and a reflection region sequentially provided in the light guiding direction at a base end of the Y-branched waveguide. In the wavelength-tunable laser, a first coupled waveguide that is one waveguide branched from the Y-branched coupled waveguide is coupled to the circling waveguide in one region, a second coupled waveguide that is the other waveguide branched from the Y-branched waveguide is coupled to the circling waveguide in another region, and the refractive index of at least part of the circling waveguide is modulated.

Advantageous Effects of Embodiments of Invention

According to embodiments of the present invention, it is possible to provide a wavelength-tunable laser that operates with low power consumption.

### BRIEF DESCRIPTION OF THE DRAWINGS

FIG. 1 is a schematic diagram illustrating a configuration of a wavelength-tunable laser according to a first embodiment of the present invention.

FIG. 2 is a schematic diagram illustrating a configuration of a wavelength-tunable laser according to a modification of the first embodiment of the present invention.

FIG. 3 is a schematic diagram illustrating a configuration of a wavelength-tunable laser according to a modification of the first embodiment of the present invention.

FIG. 4A is a diagram illustrating device characteristics in a wavelength-tunable laser according to the first embodiment of the present invention.

FIG. 4B is a diagram illustrating device characteristics in a wavelength-tunable laser according to the first embodiment of the present invention.

FIG. 4C is a diagram illustrating device characteristics in a wavelength-tunable laser according to the first embodiment of the present invention.

FIG. 4D is a diagram illustrating device characteristics in a wavelength-tunable laser according to the first embodiment of the present invention.

FIG. 5A is a diagram illustrating device characteristics in a wavelength-tunable laser according to a modification of the first embodiment of the present invention.

FIG. 5B is a diagram illustrating device characteristics in a wavelength-tunable laser according to a modification of the first embodiment of the present invention.

FIG. 5C is a diagram illustrating device characteristics in a wavelength-tunable laser according to a modification of the first embodiment of the present invention.

FIG. 6A is a diagram illustrating characteristics in a wavelength-tunable laser according to the first embodiment of the present invention.

FIG. 6B is a diagram illustrating characteristics in a wavelength-tunable laser according to the first embodiment of the present invention.

FIG. 7A is a diagram illustrating characteristics in a wavelength-tunable laser according to a modification of the first embodiment of the present invention.

FIG. 7B is a diagram illustrating characteristics in a wavelength-tunable laser according to a modification of the first embodiment of the present invention.

FIG. 8 is a schematic diagram illustrating a configuration of a wavelength-tunable laser according to a second embodiment of the present invention.

FIG. 9 is a schematic diagram illustrating a configuration of a wavelength-tunable laser according to a modification of the second embodiment of the present invention.

FIG. 10A is a diagram illustrating characteristics in a wavelength-tunable laser according to the second embodiment of the present invention.

FIG. 10B is a diagram illustrating characteristics in a wavelength-tunable laser according to the second embodiment of the present invention.

FIG. 11A is a diagram illustrating characteristics in a wavelength-tunable laser according to a modification of the second embodiment of the present invention.

FIG. 11B is a diagram illustrating characteristics in a wavelength-tunable laser according to a modification of the second embodiment of the present invention.

FIG. 12 is a schematic diagram illustrating a configuration of a wavelength-tunable laser according to a third embodiment of the present invention.

FIG. 13A is a diagram for explaining an operation of a wavelength-tunable laser according to the third embodiment of the present invention.

FIG. 13B is a diagram for explaining an operation of a wavelength-tunable laser according to the third embodiment of the present invention.

FIG. 14A is a diagram for explaining an operation of a wavelength-tunable laser according to the third embodiment of the present invention.

FIG. 14B is a diagram for explaining an operation of a wavelength-tunable laser according to the third embodiment of the present invention.

FIG. 15 is a schematic diagram illustrating a configuration of a wavelength-tunable laser according to a fourth embodiment of the present invention.

FIG. 16A is a diagram for explaining an operation of a wavelength-tunable laser according to the fourth embodiment of the present invention.

FIG. 16B is a diagram for explaining an operation of a wavelength-tunable laser according to the fourth embodiment of the present invention.

FIG. 17A is a diagram illustrating characteristics in a wavelength-tunable laser according to the fourth embodiment of the present invention.

FIG. 17B is a diagram illustrating characteristics in a wavelength-tunable laser according to the fourth embodiment of the present invention.

FIG. 18 is a schematic diagram illustrating a configuration of a wavelength-tunable laser according to a fifth embodiment of the present invention.

FIG. 19 is a diagram for explaining an operation of a wavelength-tunable laser according to the fifth embodiment of the present invention.

FIG. 20 is a schematic diagram illustrating a configuration of a wavelength-tunable laser according to the fifth embodiment of the present invention.

### DETAILED DESCRIPTION OF ILLUSTRATIVE EMBODIMENTS

### First Embodiment

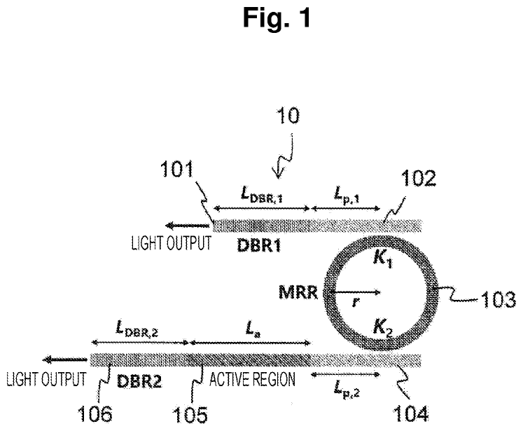

A first embodiment of the present invention is described with reference to FIGS. 1 to 7B.

Configuration of a Wavelength-Tunable Laser

As illustrated in FIG. 1, a wavelength-tunable laser 10 according to this embodiment includes a micro-ring resonator (hereinafter referred to as the “MRR”), DBRs, and an active region. Hereinafter, this wavelength-tunable laser will be also referred to as the “MRR-DBR-TLD”.

Here, the MRR does not necessarily have an upper surface that is a perfect circle in shape, but is only required to be a waveguide having a shape in which guided light circulates, such as an elliptical or polygonal shape and will be hereinafter also referred to as a “circling waveguide”.

The wavelength-tunable laser 10 includes an MRR filter formed with the MRR and two waveguides (hereinafter referred to as the “coupled waveguides”) directionally coupled to the MRR, and has a resonator structure in which the active region connected to the filter is surrounded by two DBRs. Specifically, the wavelength-tunable laser 1o includes a first DBR (first reflection region) 101, a first coupled waveguide 102, an MRR (circling waveguide) 103, a second coupled waveguide 104, an active region 105, and a second DBR (second reflection region) 106.

Here, the first coupled waveguide 102 and the second coupled waveguide 104 are both coupled to the MRR 103. In this embodiment, the waveguides 102 and 104 are coupled in regions facing each other in the MRR 103. However, the waveguides 102 and 104 are not limited to this, and may be coupled in different regions in the MRR 103.

Further, the gap (distance) between the MRR 103 and the first coupled waveguide 102 or the second coupled waveguide 104 is about 100 to 200 nm, and may be any distance at which optical coupling can be performed between the MRR 103 and the coupled waveguides 102 and 104. Here, the power coupling constant between the MRR 103 and the first coupled waveguide 102 is represented by K₁, and a power coupling constant between the MRR 103 and the second coupled waveguide 104 is represented by K₂. Further, the wavelength-tunable laser can operate even if the MRR 103 is in contact with the first waveguide 102 or the second waveguide 104.

Further, the first reflection region 101 is connected in the light guiding direction of the first coupled waveguide 102, and the active region 105 and the second reflection region 106 are sequentially connected in the light guiding direction of the second coupled waveguide 104.

In the wavelength-tunable laser 10, the length of the first DBR 101 is L_{DBR,1}, the length of the second DBR 106 is L_{DBR,2}, and the length of the active region 105 is Lₐ. Meanwhile, the radius of the MRR 103 is represented by r.

Further, in the first coupled waveguide 102, the length from the boundary with the first DBR 101 to the coupling portion with the MRR 103, which is the length of the region in which light is guided in the first coupled waveguide 102, is L_{p,1}.

Meanwhile, in the second coupled waveguide 104, the length from the boundary with the active region 105 to the coupling portion with the MRR 103, which is the length of the region in which light is guided in the second coupled waveguide 104, is L_{p,2}.

Further, the width of the second DBR is 1.5 μm, and the width of the active region is 800 nm. Meanwhile, the width of the second coupled waveguide 104 is designed to change from 1.5 μm to 500 nm in the region from the portion connecting to the active region to the portion coupled to the MRR 103, so that guided light is coupled to the MRR 103 in a single mode. Further, the waveguide width of the first DBR, the first coupled waveguide 102, and the MRR 103 is about 500 nm, and is set so that guided light can be guided in a single mode.

In the layer structure of the wavelength-tunable laser 10, an InP layer is formed as a waveguide layer on SiO₂ on a Si substrate at the portions (the first DBR, the first coupled waveguide 102, the MRR 103, the second coupled waveguide 104, and the second DBR) other than the active region. Alternatively, SiO₂, InP (waveguide), and SiO₂ may be stacked in this order. Further, the waveguide layer may be formed with a material such as a compound semiconductor or Si that can guide light in a long-wavelength band (1.3 μm, 1.55 μm, or the like).

The regions indicated by lattice patterns drawn with vertical and horizontal lines in FIG. 1 indicate the regions whose refractive indexes are modulated by resistive heating, carrier injection, or the like. As described above, in the resonator structure in the wavelength-tunable laser according to this embodiment, lasing wavelength tunability is developed by modulating the refractive index of the MRR 103, and thus, wavelength tuning in laser oscillation is enabled.

With the wavelength-tunable laser 10 according to this embodiment, an example in which light is output from both of the two DBRs to share the resonator structure has been described. However, the length of one DBR may be designed to be sufficiently long while the length of the other DBR is designed to be appropriately short so that light can be output from only the front DBR, with the former DBR being the rear DBR, the latter DBR being the front DBR.

Modifications of the First Embodiment

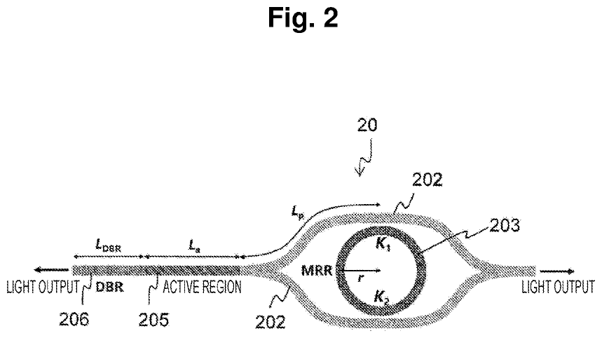

As illustrated in FIG. 2, like the wavelength-tunable laser 10, a wavelength-tunable laser 20 according to a modification of the first embodiment includes an MRR 203, a DBR (reflection region) 206, and an active region 205, but has a symmetric Y-branched waveguide 202 directionally coupled to the MRR 203. The Y-branched waveguide 202 branches from the base end portion into a first waveguide and a second waveguide. The respective waveguides are coupled in opposing regions in the MRR 203. Here, the respective waveguides may be coupled in different regions in the MRR 203.

Further, the active region 205 and the reflection region 206 are sequentially connected in the light guiding direction at the base end of the Y-branched waveguide 202. Here, the length of the first DBR 206 is L_{DBR,1}, and, in each waveguide in the Y-branched waveguide 202, the length from the boundary with the active region 205 to the portion coupled to the MRR 203 is Lₚ.

As a result, traveling waves entering the MRR 203 from one waveguide of the Y-branched waveguide 202 are reflected as backward waves from the other waveguide of the Y-branched waveguide 202, and thus, the MRR behaves as a reflecting mirror (reflection region).

The MRR mirror and the DBR surround the active region, to form a resonator. As the transmittance of the DBR and the transmittance of the MRR are appropriately designed, light can be output in any desired direction of the DBR side and the MRR side.

In the wavelength-tunable laser 20 according to this modification, the refractive index of the MRR 203 is modulated to develop lasing wavelength tunability, as in the wavelength-tunable laser 10 according to the first embodiment.

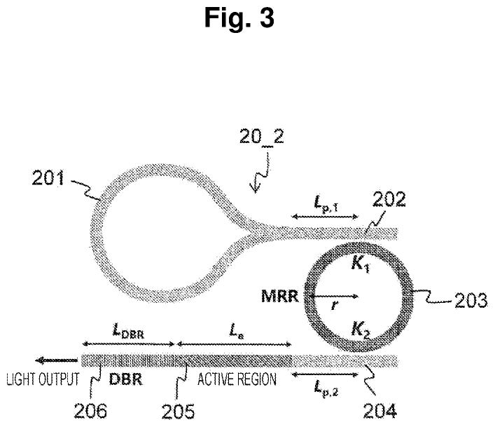

Alternatively, as in a wavelength-tunable laser 20_2 illustrated in FIG. 3, the DBR (first DBR) on the rear side in the wavelength-tunable laser 10 maybe replaced with a loop mirror 201, and reflection wavelength selection by the DBR may be performed only on the front side (second DBR).

As described above, in this embodiment, a MRR or a loop mirror, other than a DBR, can be used as a reflection region.

In this embodiment and its modifications, a configuration in which the refractive index is modulated in an entire MRR (circling waveguide) has been described as an example. However, the refractive index maybe modulated at part of a MRR (circling waveguide). Here, the wider the region in which the refractive index is modulated, the wider the wavelength-tunable region. Therefore, to expand the wavelength-tunable region, it is desirable to modulate the refractive index in the entire region of the MRR (circling waveguide).

Operations of Wavelength-Tunable Lasers

In the description below, operations of wavelength-tunable lasers according to this embodiment are explained, with the wavelength-tunable lasers 10 and 20 being examples.

For the wavelength-tunable lasers 10 and 20, a membrane structure in which an InP-based thin film is formed on an oxide film having a low refractive index such as SiO₂ is used. Here, the InP-based thin film maybe a thin film formed with a crystal such as InGaAs, InGaAsP, or InGaAlAs that is crystal-grown on an InP thin film or an InP substrate.

A membrane structure includes a low refractive index material such as SiO₂, an InP-based thin film, and a low refractive index material in this order, and the thickness of the InP-based thin film is about 250 nm to 350 nm. Strong optical confinement in the InP-based thin film is achieved. Here, the low refractive index material above the InP-based thin film may be air.

Particularly, for the active region, a membrane structure in which an InP-based thin film formed with a layer structure such as InP/InGaAsP or InP/InGaAIAs is formed on an oxide film having a low refractive index such as SiO₂ is used. (S. Matsuo, T. Fujii, K. Hasebe, K. Takeda, T. Sato, and T. Kakitsuka, “Directly modulated buried heterostructure DFB laser on SiO₂/Si substrate fabricated by regrowth of InP using bonded active layer,” Opt. Express 22, 12139-12147 (2014).).

In the active layer region having a membrane structure, a current is injected in a lateral direction (the electrode for current injection is not illustrated in the drawing). Here, in the active layer region, a current is not necessarily injected in a lateral direction, but may be injected in a longitudinal direction (a direction perpendicular to the substrate).

Further, the structure for current injection into the active layer can be obtained by forming an InGaAsP-based or InGaAlAs-based active layer in an InP thin film by a burying regrowth technique, and then forming p-type InP, an active layer, and n-type InP through dopant implantation. In this current injection structure, the active layer functions as a core.

On the other hand, passive elements such as a coupled waveguide, a DBR, and a MRR can be obtained by processing an InP thin film into a waveguide shape having an appropriate width (a thin wire structure), using reactive ion etching or the like. The DBR may have a diffraction grating formed on a surface thereof or on a sidewall of the waveguide. Alternatively, as a reflection region, a photonic crystal, instead of the DBR, maybe formed in the waveguide.

As the active region and the passive elements (regions) are formed with an InP-based material such as InP, InGaAsP, or InGaAlAs, direct connection can be achieved without the use of a tapered structure or the like, and a compact active optical device as a whole can be obtained.

In the case of a membrane structure, modulation of the refractive index of the MRR can be easily performed by providing resistive heating on an overcladding formed with SiO₂ or the like.

In a case where a wavelength-tunable laser according to this embodiment or a modification is operated without modulation of the refractive index modulation of the DBR, the coupling constant x of the DBR is a value with which the stopband width B_{DBR} substantially satisfies Expression (1).

Mathematical Expression 1

max{Δλ_{MRR}}<B_{DBR}<FSR_{MRR} (1)

Here, max {Δλ_{MRR}} represents the maximum variable width of the resonance wavelength of MRR, and FSR_{MRR} represents the intervals between resonance peaks (free spectral range: FSR) of the MRR.

When this relationship is satisfied, the following conditions preferable for TLD characteristics are satisfied: only one resonance peak of the MRR exists in the stopband of the DBR, and the peak does not deviate from the stopband of the DBR over the entire tunable range of the resonance wavelength of the MRR.

As an example, in a case where max {Δλ_{MRR}} is about 10 nm, and the MRR radius r is about 4 μm, x satisfying the above conditions is about 500 cm⁻¹ to 1000 cm⁻¹.

Since optical confinement is strong in the membrane structure, the bending loss is kept low even when the bending radius of the MRR is reduced to several μm, and preferred characteristics are achieved even when such a minute MRR is formed.

Also, in the membrane structure, the buried active region and the passive waveguide region can be compactly integrated, and the resonator can be shortened.

Further, in the formation of the DBR, if etching or the like is performed on the surface of the InP waveguide, to form a surface diffraction grating, intense refractive index modulation occurs due to the strong optical confinement, and a large coupling constant of about several hundreds of cm⁻¹ to 1000 cm⁻¹ is easily obtained. (E. Kanno, K. Takeda, T. Fujii, K. Hasebe, H. Nishi, T. Yamamoto, T. Kakitsuka, and S. Matsuo, “Twin-mirror membrane distributed-reflector lasers using 20-μm-long active region on Si substrates,” Opt. Express 26, 1268-1277 (2018).).

Alternatively, not only the MRR but also the DBR can be subjected to refractive index modulation, so that the resonance wavelength of the former and the Bragg wavelength of the latter always coincide with each other during an operation. In this case, the resonance peak of the MRR is always located at the center of the stopband of the DBR. Accordingly, to have only one resonance peak of the MRR in the stopband of the DBR, simply satisfying Expression (1′) is required. At this stage, to modulate the refractive index of the DBR, an electrode is provided on the surface of the DBR region, and a current is injected. Alternatively, a temperature adjustment mechanism such as a heater or a Peltier element maybe provided to change temperature.

Mathematical Expression 2

B_{DBR}<2×FSR_{MRR} (1′)

Thus, the upper limit of the stopband width of the DBR or the lower limit of the FSR of the MRR is extended, compared with the case of Expression (1).

Characteristics of Wavelength-Tunable Laser

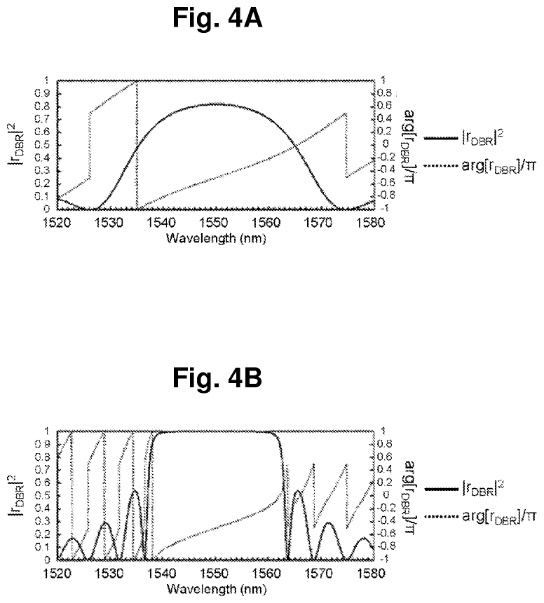

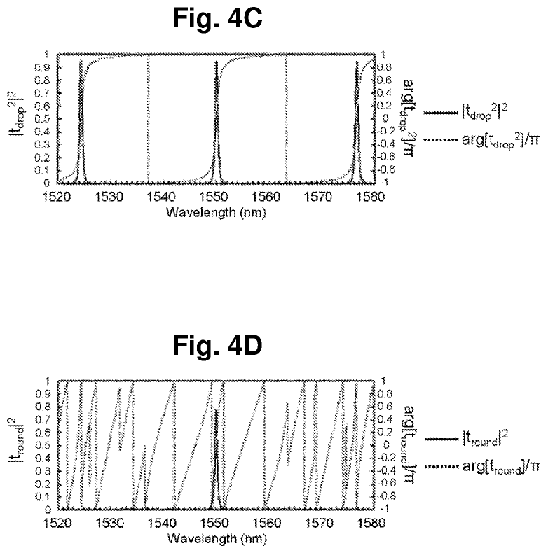

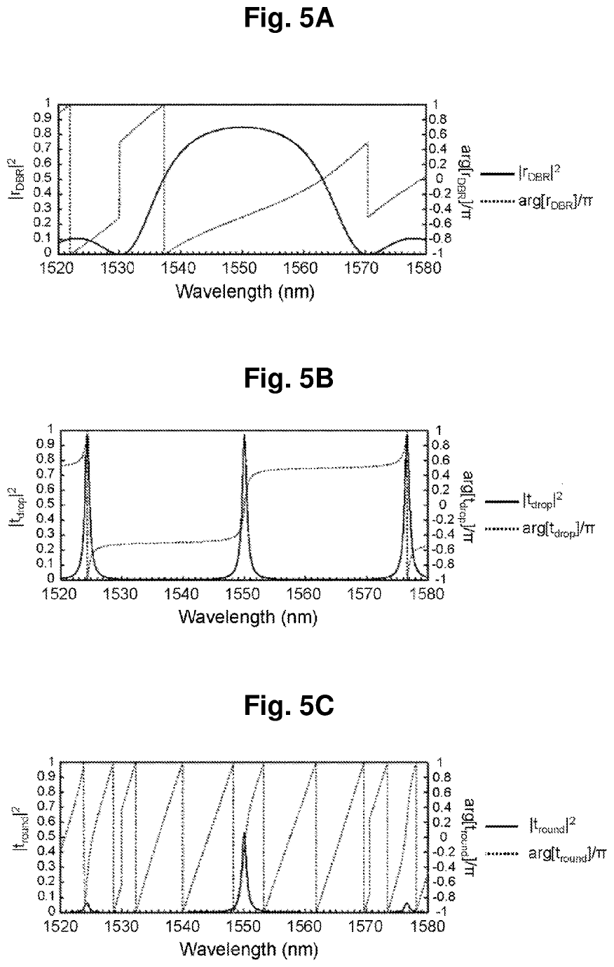

The characteristics of the wavelength-tunable lasers 10 and 20 according to this embodiment and the modifications are now described with reference to FIGS. 4A to 5C.

In the calculation of the characteristics of the wavelength-tunable lasers 10 and 20, typical values of a membrane device were used as the equivalent refractive index n_{eq} of a waveguide and its wavelength dispersion dn_{eq}/dλ. Hereinafter, λ represents the lasing wavelength of a wavelength-tunable laser according to embodiments of the present invention.

First, the amplitude reflectance r_{DBR} of the DBR, the amplitude transmittance t_{drop}indicating the filter characteristics of the MRR, and the amplitude gain coefficient t_{round} obtained when light goes around the resonator, which are illustrated in each of FIGS. 4A to 5C, are described.

As resonator characteristics of the wavelength-tunable lasers 10 and 20, the amplitude reflectance r_{DBR} of the DBR is calculated according to Expression (2).

$$\begin{matrix}Mathematical Expression 3 & \\ {r}_{DBR} ( λ ) = \frac{- j κ tanh ( γ {L}_{DBR} )}{γ + j Δβ tanh ( γ {L}_{DBR} )} & ( 2 )\end{matrix}$$

Here, Δβ=(2πn_{eq}(λ))/λ−a/π(a representing the pitch of the Bragg diffraction grating), and γ=√/(κ²−(Δβ)²).

Also, the amplitude transmittance (which is the filter characteristics of the MRR) t_{drop}from the input port to the drop port in the MRR is calculated according to Expression (3).

$$\begin{matrix}Mathematical Expression 4 & \\ {t}_{drop} ( λ ) = \frac{- \sqrt{{K}_{1}} \sqrt{{K}_{2}} {e}^{- α {L}_{ring} / 2} {e}^{- k {β}_{ring} {L}_{ring} /}}{1 - \sqrt{1 - {K}_{1}} \sqrt{1 - {K}_{2}} {e}^{- α {L}_{ring}} {e}^{- j {β}_{ring}}} & ( 3 )\end{matrix}$$

Here, K₁ and K₂ represent the power coupling constants between the MRR and the waveguide, and can take real values from 0 to 1. Meanwhile, β_{ring}=(2πn_{eq, ring}(λ))/λ, and L_{ring}=2πr represent the propagation constant and the circumferential length of the MRR, respectively. Further, α represents the constant indicating the waveguide loss of the MRR.

In the resonator structure of the wavelength-tunable laser 10, these characteristics r_{DBR1}, r_{DBR2}, and t_{drop} of elements (components of the wavelength-tunable lasers), and the amplitude coefficient e^{-j(βaLa+βp, 1Lp, 1+βp, 2Lp, 2)} indicating the propagation in the waveguide region are used in calculating the amplitude gain coefficient t_{round} when light goes round the resonator (round-trip) as shown in Expression (4).

Mathematical Expression 5

t_{round}(λ)=r_{DBR,1}r_{DBR,2}t_{drop}²e^{-2∫(β}^{ₐ}^{L}^{ₐ}^{+β}^{_{p,1}}^{L}^{_{p,1}}^{+n′}^{_{p,2}}⁾ (4)

Likewise, in the resonator structure of the wavelength-tunable laser 20, tᵣₒuna is calculated as shown in Expression (5).

Mathematical Expression 6

t_{round}(λ)=Cr_{DBR}t_{drop}e^{-2j(β}^{ₐ}^{L}^{ₐ}^{+β}^{ₚ}^{L}^{ₚ}⁾ (5)

Here, C represents the coefficient indicating the power loss in the Y-branched portion. When light goes around the resonator, the light passes through the MRR filter twice in the resonator structure of the wavelength-tunable laser 10, while the light passes through the MRR filter only once in the resonator structure of the wavelength-tunable laser 10. This difference is reflected in the index of t_{drop}.

Here, to discuss the passive characteristics of the resonator, the active region is put into a transparent condition, and βₐ is a real number.

Tables 1 and 2 show the device parameters used in calculating the resonator characteristics of the wavelength-tunable lasers 10 and 20, respectively. Note that, in the calculation of the characteristics of wavelength-tunable lasers according to embodiments of the present invention, the values shown in Table 1 are used for the four parameters r, α, K₁, and K₂ that determine the characteristics of the MRR.

TABLE 1

| Parameter | Value | |
|---|---|---|
| r | 4 | μm |
| α | 0.576 | cm⁻¹ |
| K₁ | 0.1 | |
| K₂ | 0.1 | |
| Lₐ | 20 | μm |
| L_{p, 1} | 5 | μm |
| L_{p, 2} | 5 | μm |
| L_{DBR, 1} | 15 | um |
| L_{DBR, 2} | 50 | μm |
| κ₁ | 1000 | cm⁻¹ |
| κ₂ | 1000 | cm⁻¹ |

TABLE 2

| Parameter | Value | |
|---|---|---|
| Lₐ | 20 | μm |
| Lₚ | 13 | μm |
| L_{DBR} | 20 | μm |
| κ | 800 | cm⁻¹ |

| | |
|---|---|
| C | 0.8 |

FIGS. 4A to 4D show r_{DBR1}, r_{DBR2}, t_{drop}, and t_{round} of the wavelength-tunable laser 10, respectively. Likewise, FIGS. 5A to 5C show r_{DBR}, t_{drop}, and t_{round} of the wavelength-tunable laser 20.

In FIGS. 4A, 4B, and 5A, the stopband width of the DBR is slightly smaller than the FSR of the MRR, and the relationship expressed by Expression (1) is satisfied. Here, when the refractive index modulation of the MRR is modulated in the structures of the wavelength-tunable lasers 10 and 20, the shift amount of the resonance wavelength is given by Expression (6).

Mathematical Expression 7

$${Δλ}_{MRR} = \frac{Δ {n}_{eq , ring}}{{n}_{g , ring}} λ \qquad ( 6 )$$

Here, Δn_{eq, ring}, and n_{g, ring} are the amount of change in the equivalent refractive index and the group refractive index of the waveguides forming the MRR. In a case where a refractive index change due to a temperature rise caused by resistive heating is utilized, the equivalent refractive index change amount per unit temperature rise is about Δn_{eq}/ΔT to 2×10⁻⁴ K⁻¹ in an InP waveguide. Therefore, in a case where the temperature of the waveguide is raised by 100 K, for example, an equivalent refractive index change of about Δn_{eq} to 0.02 can be obtained.

In an example calculation in this embodiment, in a case where n_{g,ring}=3.66, and λ=1550 nm, the resonance wavelength shift amount of the MRR at a time of a temperature rise of 100 K is estimated to be Δλ_{MRR} to 8.5 nm. In the wavelength-tunable lasers 10 and 20, large coupling constants of 1000 cm⁻¹ and 800 cm⁻¹ provide a sufficient stopband width for realizing the wavelength-tunable range, and the relationship expressed by Expression (1) is satisfied.

In FIGS. 4D and 5C, the amplitude gain coefficients obtained when light goes around the resonator are plotted. Since the resonance condition of light is given by arg[t_{round}]=0, the wavelength at which the dashed line indicating the phase (deflection angle) of the amplitude gain coefficient indicates zero is the longitudinal-mode resonance wavelength of the entire resonator. There is a plurality of points that satisfy this resonance condition, and the mode in which the threshold gain is minimized among the points oscillates.

In this case, when attention is paid to the wavelength characteristics of the phase in the DBR stopband, it is clear that the phase rapidly rotates (changes) around the resonance peak of the MRR. This is because the effective length of the MRR becomes specifically longer at its resonance wavelength, that is, light travels through the MRR multiple times at the resonance wavelength. As a result, one point satisfying the above resonance condition always appears around the resonance peak of the MRR.

This means that, when the resonance peak wavelength of the MRR is swept by refractive index modulation of the MRR, the longitudinal-mode resonance wavelength is automatically swept following the resonance peak wavelength of the MRR, and thus, lasing wavelength tunability can be achieved without longitudinal-mode phase adjustment.

Further, the interval between points that satisfy the resonance condition, which is the longitudinal-mode FSR, is sufficiently wider than the resonance peak linewidth of the MRR, and the MRR that is a filter having a sharp passband is used. Thus, preferable single-mode characteristics can be achieved.

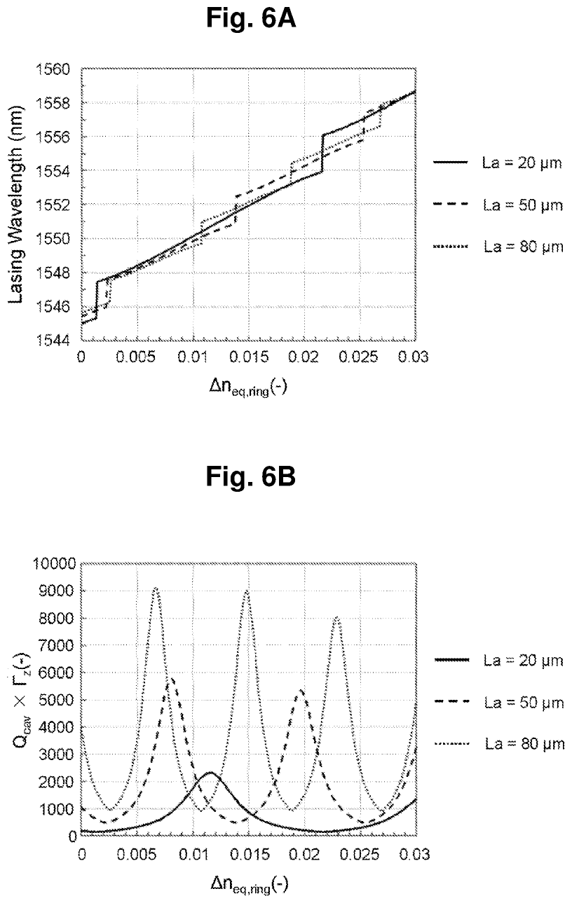

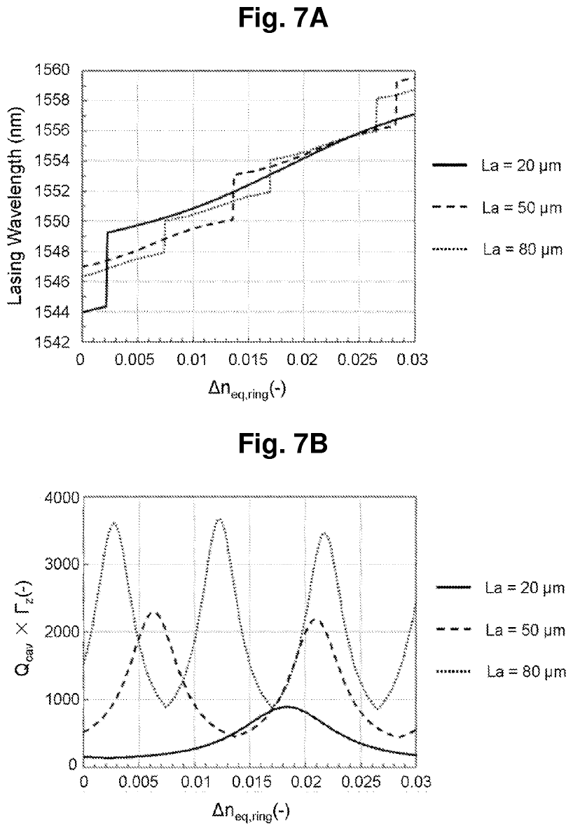

Next, the characteristics of the wavelength-tunable lasers 10 and 20 are described with reference to FIGS. 6A to 7B.

Calculations were performed, with the active region length La being La=20 μm, 50 μm, and 80 μm. As for the parameters other than the active region length, the values shown in Tables 1 and 2 were used. Here, the performance index Q_{cav}Γ_{z} shown in Expression (7) is used as the index of the lasing threshold properties of the TLD.

$$\begin{matrix}Mathematical Expression 8 & \\ {Q}_{cav} \times {Γ}_{z} = - \frac{4 π}{λ} \frac{{Σ}_{i} {n}_{g , i} {L}_{eff , i}}{log {\vert {t}_{round} \vert}^{2}} \times \frac{{L}_{a}}{{Σ}_{i} {L}_{eff , i}} & ( 7 )\end{matrix}$$

Here, the index i represents each of the parts constituting the resonator, and Σ means that the sum of all the parts is taken. L_{eff,i} represents the effective length of the part i. Further, Q_{cav} represents the quality factor of the resonator, and Γ_{z} represents the optical confinement factor of the active region in the optical axis direction.

As for the lasing wavelength illustrated in FIG. 6A, the wavelength having the lowest threshold gain in a plurality of wavelengths satisfying the resonance condition, which is the wavelength at which Q_{cav}Γ_{z} is maximized according to Expression (7), was calculated. Further, Q_{cav}Γ_{z} shown in FIG. 6B was calculated according to Expression (7).

In the wavelength-tunable laser, the z direction is the optical axis direction (the traveling direction of guided light), the y direction is a direction perpendicular to the substrate, and the x direction is a direction perpendicular to the z direction and the y direction.

Since the threshold gain of the LD is inversely proportional to the product of the quality factor and the optical confinement factor, the lasing threshold properties derived from the resonator characteristics can be discussed on the basis of this index. In the membrane structure, optical confinement in a waveguide cross-section (x-y plane) is strong, and Γ_{xy} is large, as described above For example, Q_{cav}Γ_{z} of about 1,000 or greater maybe used as a criterion for low threshold lasing.

As for lasing wavelength tunability, when Lₐ=20 μm, a wide hop-free variable range of 6.4 nm is obtained in FIG. 6A. If the active region length is increased from Lₐ=20 μm, the hop-free variable range becomes narrower as the longitudinal-mode FSR becomes shorter. However, a sufficiently wide hop-free variable range on the nm order (2.1 nm) is obtained even when Lₐ=80 μm.

The preferable hop-free characteristics were achieved by taking advantage of the features of the membrane structure, which are that the entire resonator can be shortened, and a wide longitudinal-mode FSR can be maintained.

As for the Q_{cav}Γ_{z} tuning characteristics, Q_{cav}Γ_{z} in FIG. 6B shows the maximum value near the center of the hop-free variable region, and shows the minimum value at the wavelength at which mode hopping occurs. This is because detuning of the longitudinal-mode resonance wavelength and the resonance wavelength of the MRR changes in a cycle corresponding to the longitudinal-mode FSR.

Further, according to Expression (7), the value of Q_{cav}Γ_{z} is substantially proportional to the active region length, and therefore, it is advantageous that the active region is longer in view of lasing threshold properties.

On the other hand, as illustrated in FIGS. 7A and 7B, the wavelength-tunable laser 20 qualitatively exhibits the same tendency as the wavelength-tunable laser 10, but the hop-free variable range is narrower than that of the wavelength-tunable laser 10, and is narrower than the mode hopping range of the wavelength-tunable laser 20.

The reason for this aspect is as follows. In the structure of the wavelength-tunable laser 10, rapid phase rotation by the MRR is 2π, as light travels back and forth through the MRR filter. In the structure of the wavelength-tunable laser 20, on the other hand, light passes through the MRR only once, and phase rotation remains at π. Therefore, the followability of the resonance wavelength of the structure of the wavelength-tunable laser 20 is inferior to that of the structure of the wavelength-tunable laser 10.

Effects

With a wavelength-tunable laser according to this embodiment or its modification, it is possible to obtain lasing wavelength tunability having a hop-free variable range on the order of nm through refractive index modulation performed only on a very compact MRR of several μm in radius, without any phase adjustment.

Further, with the above-described lasing wavelength tunability, the power consumption required for refractive index modulation can be made lower than that with a DBR-TLD, and thus, a TLD with low total power consumption can be obtained.

Also, the time and effort for phase adjustment that normally requires complicated control can be saved, and easy-to-control hop-free tuning can be achieved with a two-electrode configuration formed with an active region electrode and a wavelength control electrode.

### Second Embodiment

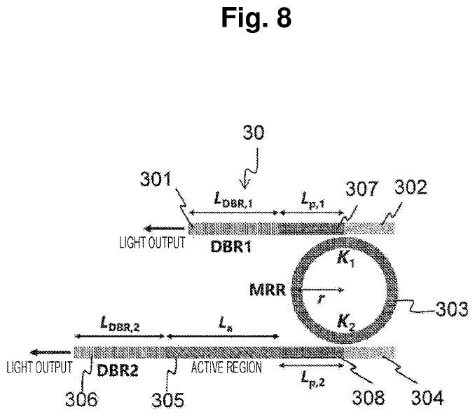

A wavelength-tunable laser according to a second embodiment of the present invention is now described with reference to FIGS. 8 to 11. A wavelength-tunable laser according to this embodiment can further expand the mode-hop-free variable range, compared with a wavelength-tunable laser according to the first embodiment.

Configuration of a Wavelength-Tunable Laser

As illustrated in FIG. 8, a wavelength-tunable laser 30 according to this embodiment includes regions having a refractive index modulation mechanism in the coupled waveguides (hereinafter, these regions will be referred to as “modulation regions”) in the configuration of the wavelength-tunable laser 10 according to the first embodiment.

A first modulation region 307 is disposed in a first coupled waveguide 302 between the boundary with a first DBR 301 and the portion coupled to a MRR 303, and has a length L_{p,1}. That is, the first modulation region 307 is disposed in the region where light is guided in the first coupled waveguide 302.

Also, a second modulation region 308 is disposed in a second coupled waveguide 304 between the boundary with an active region 305 and the portion coupled to the MRR 303, and has a length L_{p,2}. That is, the second modulation region 308 is disposed in the region where light is guided in the second coupled waveguide 304.

In this manner, the first modulation region 307 and the second modulation region 308 are coupled to the MRR 303.

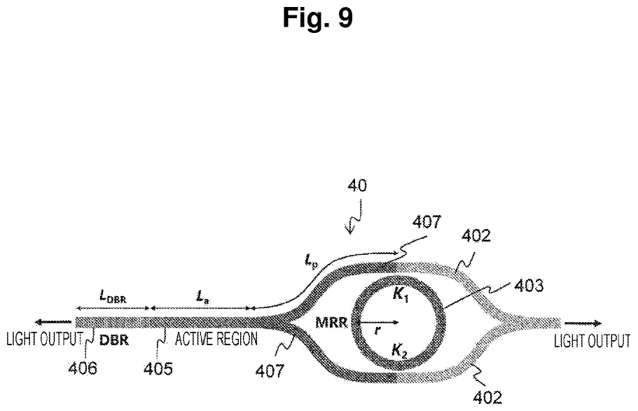

As a modification of this embodiment, a wavelength-tunable laser 40 further includes a Y-branched modulation region in the wavelength-tunable laser 20 according to a modification of the first embodiment, as illustrated in FIG. 9.

A Y-branched modulation region 407 is disposed in a Y-branched waveguide 402 between the boundary with an active region 405 and the portions of the respective waveguides coupled to a MRR 403, and each of the waveguides has a length Lₚ. That is, the Y-branched modulation region 407 is disposed in the region where light is guided in the Y-branched waveguide 402.

In the wavelength-tunable laser 30, the electrodes for the first modulation region 307 and the second modulation region 308 are short-circuited with the electrode for the MRR, and the refractive index is modulated with identical electrodes and substantially identical control signals.

Meanwhile, in the wavelength-tunable laser 40, the electrodes for the Y-branched modulation region 407 is short-circuited with the electrode for the MRR, and the refractive index is modulated with identical electrodes and substantially identical control signals.

In this embodiment and its modifications, a configuration in which the refractive index is modulated in an entire MRR (circling waveguide) has been described as an example. However, the refractive index maybe modulated at part of a MRR (circling waveguide). Here, the wider the region in which the refractive index is modulated, the wider the wavelength-tunable region. Therefore, to expand the wavelength-tunable region, it is desirable to modulate the refractive index in the entire region of the MRR (circling waveguide).

In the examples described above, each of the modulation regions 307, 308, and 407 is disposed in the entire region where light is guided in the waveguide (a coupled waveguide or a Y-branched waveguide) coupled to a MRR. However, the refractive index may be modulated in part of the region where light is guided in the waveguide coupled to the MRR. Here, the larger the region in which the refractive index is modulated, the wider the wavelength-tunable region. Therefore, to expand the wavelength tunable range, it is desirable to modulate the refractive index in the entire region where light is guided.

Further, in this embodiment and its modifications, even if identical electrodes are not provided in the respective modulation regions and MRR, the respective electrodes maybe electrically connected by an electric wiring line or the like, and the refractive indexes may be modulated with substantially identical control signals.

Alternatively, even if the respective electrodes are not electrically connected, the refractive indexes may be modulated with substantially identical control signals. Here, in the substantially identical control signals, the current amount changes and the time changes may be substantially identical, and at least the time changes are required to be substantially identical.

Here, each refractive index maybe modulated not only with a control signal generated by an injected current, but also with a control signal generated by a temperature or the like.

In this manner, the refractive indexes in the modulation region and the MRR maybe modulated at substantially the same time.

Hereinafter, “substantially identical” and “substantially the same time” include “completely identical”, and also include cases where there is a small difference with which a wavelength-tunable laser according to this embodiment can operate.

Operations of Wavelength-Tunable Lasers

In the description below, operations of the wavelength-tunable lasers 30 and 40 are explained. The longitudinal-mode resonance wavelength shift amount of the entire resonator in the wavelength-tunable laser 30 is given by Expression (8).

$$\begin{matrix}Mathmematical Expression 9 & \\ {Δλ}_{cav} = \frac{Δ {n}_{eq , ring} ( {L}_{p , 1} + {L}_{p , 2} + {L}_{ring} / 2 )}{\begin{matrix}{n}_{g , a} {L}_{a} + {n}_{g , p , 1} {L}_{p , 1} + {n}_{g , p , 2} {L}_{p , 2} + \\ {n}_{g , DBR , 1} {L}_{eff , DBR , 1} + \\ {n}_{g , DBR , 2} {L}_{eff , DBR , 2} + {n}_{g , ri}\end{matrix}} \frac{}{{}_{g} / 2} & ( 8 )\end{matrix}$$

Likewise, the shift amount in the wavelength-tunable laser 40 is given by Expression (9).

$$\begin{matrix}Mathematical Expression 10 & \\ {Δλ}_{cav} = \frac{Δ {n}_{eq , ring} ( {L}_{p} + {L}_{ring} / 2 )}{{n}_{g , a} {L}_{a} + {n}_{g , p ,} {L}_{p ,} + {n}_{g , DBR} {L}_{eff , DBR} + {n}_{g , ring} {L}_{ring} / -} & ( 9 )\end{matrix}$$

Accordingly, refractive index modulation is also performed on the passive waveguide portions as well as the MRR, so that the longitudinal-mode resonance wavelength shifts to the long wavelength side like that of the MRR, and the followability of the longitudinal-mode resonance wavelength with respect to the resonance peak wavelength of the MRR becomes higher.

Characteristics of Wavelength-Tunable Laser

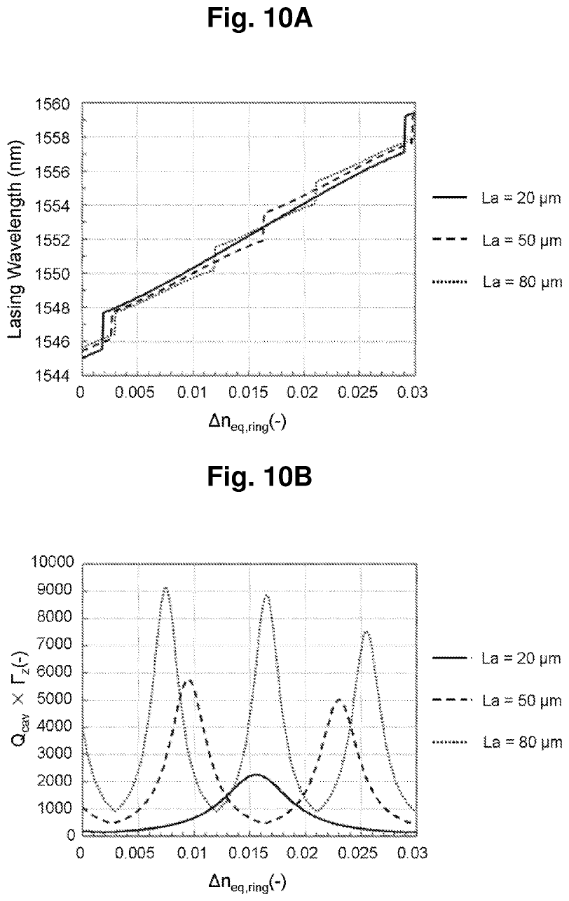

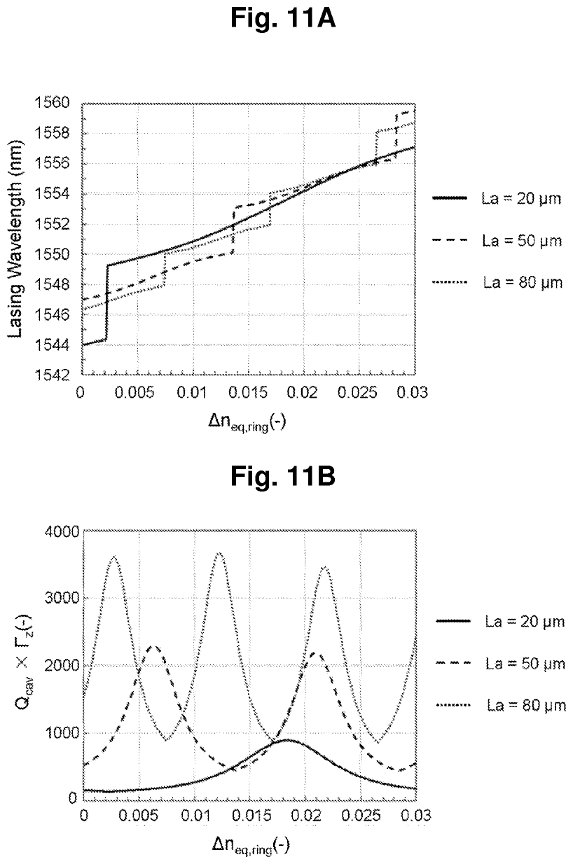

FIGS. 10A and 10B each show lasing wavelength and Q_{cav}Γ_{z} as characteristics of the wavelength-tunable laser 30. Also, FIGS. 11A and 11B each show lasing wavelength and Q_{cav}Γ_{z} as characteristics of the wavelength-tunable laser 40. The conditions other than the presence/absence of refractive index modulation in the passive waveguides are the same as those in the first embodiment and its modifications.

The mode hopping ranges of the wavelength-tunable lasers 30 and 40 are similar to those in the wavelength-tunable lasers 10 and 20 (FIGS. 6A to 7B). On the other hand, the hop-free variable ranges are greatly expanded, compared with those in the wavelength-tunable lasers 10 and 20 (FIGS. 6A to 7B). As the refractive indexes of the passive waveguides as well as the MRR are modulated in this manner, the hop-free variable ranges are expanded.

Effects

As described above, the refractive indexes of the passive waveguide regions between the active region and the MRR are modulated with the same electrodes and the same control signals as those for the MRR, the mode-hop-free variable range is expanded, and the wavelength region that can be covered becomes wider.

Further, as identical electrodes and identical control signals are used, an operation can be performed as an operation of a two-electrode configuration, and control can be easily performed.

### Third Embodiment

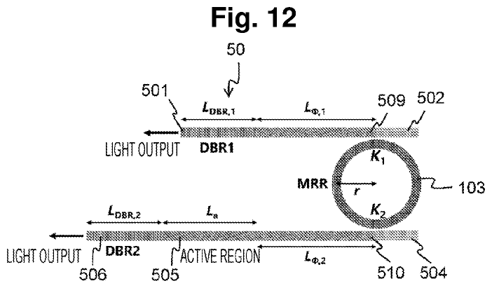

A wavelength-tunable laser according to a third embodiment of the present invention is now described with reference to FIGS. 12 to 14B. A wavelength-tunable laser 50 according to this embodiment further includes a longitudinal-mode phase adjustment region, compared with the wavelength-tunable laser 10 according to the first embodiment. As the longitudinal-mode phase determines the absolute positions of the hop-free variable region and the mode hopping region, the wavelength-tunable laser 50 is effective in a case where controllability for the absolute wavelength is required.

Configuration of a Wavelength-Tunable Laser

As illustrated in FIG. 12A, in the wavelength-tunable laser 50, a first phase adjustment region 509 is disposed in a first coupled waveguide 502 between the boundary with a first DBR 501 and the portion coupled to a MRR 503, and has a length L_{Φ,1.} That is, the first phase adjustment region 509 is disposed in the region where light is guided in the first coupled waveguide 502.

Also, a second phase adjustment region 510 is disposed in a second coupled waveguide 504 between the boundary with an active region 505 and the portion coupled to the MRR 503, and has a length L_{Φ,2}. That is, the second phase adjustment region 510 is disposed in the region where light is guided in the second coupled waveguide 504.

In this manner, the first phase adjustment region 509 and the second phase adjustment region 510 are coupled to the MRR 503.

In the wavelength-tunable laser 50, the first phase adjustment region 509 and the second phase adjustment region 510 are subjected to refractive index modulation independently of the MRR 503. Therefore, electrodes are provided in the first phase adjustment region 509, the second phase adjustment region 510, and the MRR 503 separately from one another, and the respective refractive indexes are modulated with different control signals. Here, signals having at least different time changes maybe used as the different control signals.

In this manner, the wavelength-tunable laser 50 has a three-electrode structure in which electrodes are provided in the active region 505, the MRR 503, and the phase adjustment regions 509 and 510.

Here, the first phase adjustment region 509 and the second phase adjustment region 510 are electrically connected, and the refractive indexes are modulated with substantially identical control signals. In this case, the refractive indexes of the first phase adjustment region 509 and the second phase adjustment region 510 are modulated at substantially the same time. Alternatively, the first phase adjustment region 509 and the second phase adjustment region 510 may not be electrically connected, and the refractive indexes may be modulated with different control signals. Here, a configuration in which the first phase adjustment region 509 and the second phase adjustment region 510 are electrically connected can be more easily controlled in an operation of the wavelength-tunable laser 50.

Here, each refractive index maybe modulated not only with a control signal generated by an injected current, but also with a control signal generated by a temperature or the like.

In this embodiment and its modifications, a configuration in which the refractive index is modulated in an entire MRR (circling waveguide) has been described as an example. However, the refractive index maybe modulated at part of a MRR (circling waveguide). Here, the wider the region in which the refractive index is modulated, the wider the wavelength-tunable region. Therefore, to expand the wavelength-tunable region, it is desirable to modulate the refractive index in the entire region of the MRR (circling waveguide).

Also, in the example described above, the first phase adjustment region 509 and the second phase adjustment region 510 are disposed in the entire regions where light is guided in the first coupled waveguide 502 and the second coupled waveguide 504, respectively. However, the refractive index may be modulated in part of the region where light is guided in each of the first coupled waveguide 502 and the second coupled waveguide 504. Here, the larger the region in which the refractive index is modulated, the wider the wavelength-tunable region. Therefore, to expand the wavelength tunable range, it is desirable to modulate the refractive index in the entire region where light is guided.

Operations of Wavelength-Tunable Lasers

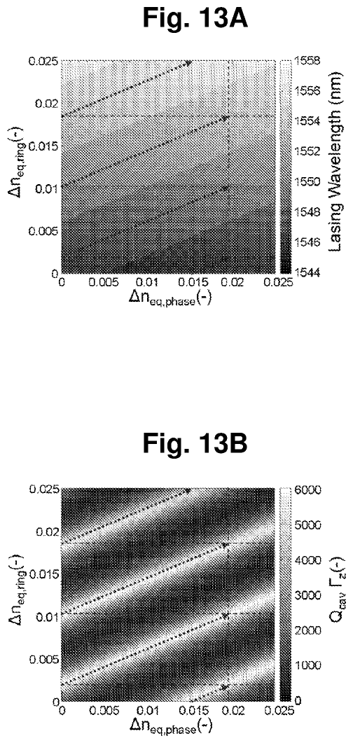

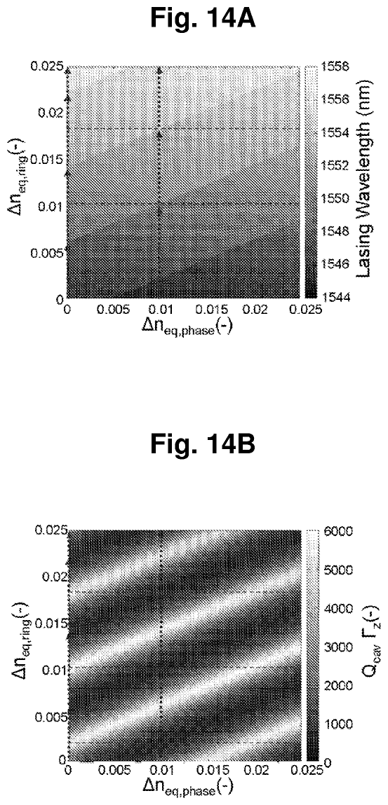

Operations of the wavelength-tunable laser 50 are now described. FIGS. 13A to 14B illustrate characteristics of wavelength-tunable laser 50. These characteristics were calculated using the device parameters shown in Table 3.

TABLE 3

| Parameter | Value | |
|---|---|---|
| Lₐ | 50 | μm |
| L_{ϕ, 1} | 20 | μm |
| L_{ϕ, 2} | 20 | μm |
| L_{DBR, 1} | 15 | μm |
| L_{DBR, 2} | 50 | μm |
| κ₁ | 1000 | cm⁻¹ |
| κ₂ | 1000 | cm⁻¹ |

The wavelength-tunable laser 50 operates by two methods for controlling lasing wavelength.

First, a first control method is now described with reference to FIGS. 13A and 13B. By the first control method, the refractive index modulation amount Δn_{eq,phase} for phase adjustment and the refractive index modulation amount Δn_{eq,ring} for the MRR are simultaneously swept at a constant ratio so that the longitudinal-mode resonance wavelength always coincides with the resonance wavelength of the MRR.

FIG. 13A illustrates the lasing wavelength among the characteristics of the wavelength-tunable laser 50 in the form of a function with two variables Δn_{eq,phase} and Δn_{eq,ring}. A region in which the lasing wavelength is close to 1558 nm is shown in white, and a region in which the lasing wavelength is close to 1544 nm is shown in black. As indicated by dashed arrows in the graph, the lasing wavelength is periodically maintained constant for each FSR, and the refractive index modulation amount Δn_{eq,phase} for phase adjustment and the refractive index modulation amount Δn_{eq, ring} for the MRR is increased so that wavelength sweep can be performed.

FIG. 13B illustrates Q_{cav}Γ_{z} among the characteristics of the wavelength-tunable laser 60 in the form of a function with two variables Δn_{eq,phase} and Δn_{eq, ring}. A region in which Q_{cav}Γ_{z} is close to the maximum value is shown in white, and a region in which Q_{cav}Γ_{z} is close to the minimum value is shown in black. As indicated by dashed arrows in the graph, the lasing wavelength is swept periodically for each FSR while Q_{cav}Γ_{z} always maintains a maximum value.

By the first control method, it is necessary to cover the variable range equivalent to one longitudinal-mode FSR for modulation in one cycle, and it is necessary to satisfy Expression (10).

$$\begin{matrix}Mathematical Expression 11 & \\ max \{ Δ {n}_{eq , phase} \} \times {L}_{Φ} \geq \frac{λ}{2} & ( 10 )\end{matrix}$$

Here, L_{Φ}=L_{Φ,1}+L_{Φ,2}. For example, in a case where max{Δn_{eq, phase}=}0.02 (almost equivalent to a temperature rise of +100 K), the necessary phase adjustment length is L_{Φ} to 40 μm.

Note that it is necessary to reset the phase adjustment amount every time the variable range equivalent to one longitudinal-mode FSR is passed, and shift to the next adjacent longitudinal mode. However, since a membrane structure capable with which the entire resonator can be shortened is adopted in embodiments of the present invention as described above, the FSR has a large value on the order of nm, and the frequency of resetting can be reduced to a small value.

Next, a second control method is described with reference to FIGS. 14A and 14B. By the second control method, to fill a mode hopping region that is generated when only Δn_{eq, ring} is swept, switching is performed between the two values: the value in a case where the longitudinal-mode phase adjustment amount is 0(Δn_{eq,phase}=0), and the value in a case where the longitudinal-mode phase adjustment amount is π [Δn_{eq,phase}=π/(4L_{Φ}), which is Δn_{eq,phase}=0.01 in FIG. 14].

Like FIGS. 13A and 13B, FIGS. 14A and 14B illustrate the lasing wavelength and Q_{cav}Γ_{z} among the characteristics of the wavelength-tunable laser 60 in the form of a function with two variables Δn_{eq,phase} and Δn_{eq,ring}. As indicated by dashed arrows in the graph in FIG. 14A, it is possible to perform wavelength sweep by changing only Δn_{eq,ring} while periodically switching between the two values, which are the value in a case where the phase adjustment amount is 0 (Δn_{eq,phase}=0) and the value in a case where the phase adjustment amount is π(Δn_{eq,phase}=0.01), for each FSR.

Here, in FIG. 14B, when wavelength is swept as indicated by dashed arrows in the graph, the value of Q_{cav}Γ_{z} fluctuates. On the other hand, simultaneous control of Δn_{eq,phase} and Δn_{eq, ring} is unnecessary.

Further, the conditions for the necessary phase adjustment amount are relaxed as shown in Expression (11).

$$\begin{matrix}Mathematical Expression 12 & \\ max \{ Δ {n}_{eq , phase} \} \times {L}_{Φ} \geq \frac{λ}{4} & ( 11 )\end{matrix}$$

By the second control method, to cover the entire variable range of the resonance wavelength of the MRR without any gap, it is necessary to satisfy the condition: the hop-free variable region is wider than the mode hopping region.

In the example described in this embodiment, phase adjustment is performed, with the wavelength-tunable laser 10 being the basic structure. However, in the structures of the wavelength-tunable lasers 20, 20_2, 30, and 40, it is also possible to perform phase adjustment by modulating the refractive indexes of passive waveguide portions.

Effects

As described above, with a wavelength-tunable laser according to this embodiment, the phase is rotated (changed) by the amount equivalent to 2π, so that the longitudinal-mode resonance wavelength can always match the resonance wavelength of the MRR. By this control method, the entire resonator of the membrane structure is short. Accordingly, the longitudinal-mode FSR is wide, and the lasing wavelength change per one cycle of 2π phase rotation can be large. As a result, the frequency at which the phase is reset can be reduced, and the three-electrode configuration can be controlled with relative ease.

Further, it is also possible to perform switching between two values that are a value in a state where the phase is not rotated and a value in a state where the phase is rotated by the amount equivalent to π. By this control method, operations can be performed, with the maximum phase rotation amount being a. Thus, the power consumption required for phase adjustment can be made lower than that in a case where the phase is rotated by the amount equivalent to 2π.

### Fourth Embodiment

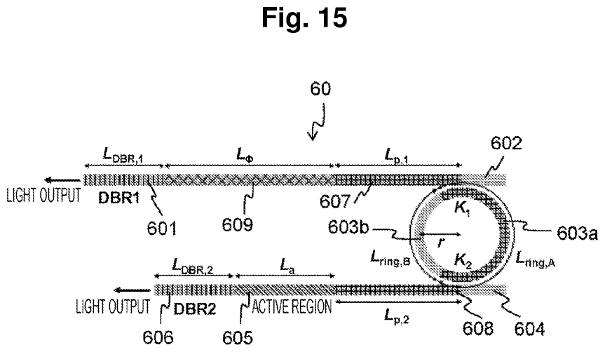

A wavelength-tunable laser according to a fourth embodiment of the present invention is now described with reference to FIGS. 15 to 17B.

As described above, to constantly match the longitudinal-mode resonance wavelength with the resonance wavelength of the MRR in the wavelength-tunable laser 50 according to the third embodiment, it is necessary to simultaneously control Δn_{eq,phase} and Δn_{eq,ring}. Also, resetting the phase adjustment amount is also required, though less frequently. In this manner, controlling the wavelength-tunable laser 50 is complicated.

A wavelength-tunable laser 60 according to this embodiment can solve the trade-off between stability of lasing operations and ease of control.

Configuration of a Wavelength-Tunable Laser

The wavelength-tunable laser 60 according to this embodiment further includes modulation regions and a longitudinal-mode phase adjustment region, compared with the wavelength-tunable laser 10 according to the first embodiment.

As illustrated in FIG. 15, in the wavelength-tunable laser 60, a phase adjustment region 609 and a first modulation region 607 are disposed in a first coupled waveguide 602. Here, the first modulation region 607 is disposed between the boundary with the phase adjustment region 609 and the portion coupled to a MRR 603. That is, the first modulation region 607 is disposed in the region where light is guided in the first coupled waveguide 602. The lengths of the phase adjustment region 609 and the first modulation region 607 are L_{Φ,1}, and L_{p,1}, respectively.

Also, a second modulation region 608 is disposed in a second coupled waveguide 604 between the boundary with an active region 605 and the portion coupled to the MRR 603, and has a length L_{p,2}. That is, the second modulation region 608 is disposed in the region where light is guided in the second coupled waveguide 604.

In this manner, the first modulation region 607 and the second modulation region 608 are coupled to the MRR 603.

Also, identical electrodes are provided in a portion 603a of the length L_{ring,A} of the MRR 603, the first modulation region 607, and the second modulation region 608, and the refractive indexes are modulated with substantially identical control signals. With this arrangement, only the portion 603a having the length L_{ring, A} in the MRR 603 is selectively subjected to refractive index modulation, and the first modulation region 607 and the second modulation region 608 are also subjected to refractive index modulation at substantially the same time.

Further, in the phase adjustment region 609, an electrode independent of the above-electrodes (in the MRR 603a, the first modulation region 607, and the second modulation region 608) is provided, and the phase adjustment region 609 is independently subjected to refractive index modulation to adjust the phase.

In this embodiment, an example configuration in which the portion that modulates the refractive index of the MRR (a circling waveguide) includes the portions coupled to the first and second coupled waveguides has been described. However, the portion that modulates the refractive index of the MRR (circling waveguide) may not include the portions coupled to the coupled waveguides. Here, in the configuration in which the portion that modulates the refractive index of the MRR includes the portions coupled to the coupled waveguides, identical can be easily disposed in the MRR and the coupled waveguides as described later.

Also, in the example described above, the first modulation region 607 and the second modulation region 608 are disposed in the entire regions where light is guided in the first coupled waveguide 602 and the second coupled waveguide 604, respectively. However, the refractive index may be modulated in part of the region where light is guided in each of the first coupled waveguide 602 and the second coupled waveguide 604.

In this embodiment, the region for modulating the refractive index in each of the MRR 603, the first modulation region 607, and the second modulation region 608 is only required to satisfy Δλ_{MRR}=Δλ_{cav}.

Further, in this embodiment, even if identical electrodes are not provided in the respective modulation regions and part of the MRR, the respective electrodes maybe electrically connected by an electric wiring line or the like, and the refractive indexes may be modulated with substantially identical control signals.

Alternatively, even if the respective electrodes are not electrically connected, the refractive indexes may be modulated with substantially identical control signals. Here, in the substantially identical control signals, the current amount changes and the time changes may be substantially identical, and at least the time changes are required to be substantially identical.

Here, each refractive index maybe modulated not only with a control signal generated by an injected current, but also with a control signal generated by a temperature or the like.

As described above, the respective refractive indexes of the portion 603a of the length L_{ring,A} of the MRR 603, the first modulation region 607, and the second modulation region 608 are only required to be modulated at substantially the same time.

In the above configuration, the filter characteristics of the MRR shown in Expression (3) are transformed into Expression (12).

$$\begin{matrix}Mathematical Expression 13 & \\ {t}_{drop} ( λ ) = \frac{- \sqrt{{K}_{1}} \sqrt{{K}_{2}} {e}^{- α {L}_{ring} / 2} {e}^{- k {β}_{ring} {L}_{ring} / 2}}{1 - \sqrt{1 - {K}_{1}} \sqrt{1 - {K}_{2}} {e}^{- α {L}_{ring}} {e}^{- j ( {β}_{ring , A} {L}_{ring , A} + {β}_{ring , B} {L}_{ring , B} )}} & ( 12 )\end{matrix}$$

Here, L_{ring, A}+L_{ring, B}=L_{ring}. At the time of refractive index modulation, only β_{ring,A} in Expression (12) is changed.

As a result, the resonance wavelength shift amount becomes as shown in Expression (13), and is limited to L_{ring,A}/L_{ring} times the amount in a case where the entire MRR is subjected to refractive index modulation.

$$\begin{matrix}Mathematical Expression 14 & \\ {Δλ}_{MRR} = \frac{{L}_{ring , A}}{{L}_{ring}} \frac{Δ {n}_{eq , ring}}{{n}_{g , ring}} λ & ( 13 )\end{matrix}$$

On the other hand, the longitudinal-mode resonance wavelength shift amount obtained when Δn_{eq,ring} is also changed is given by Expression (14).

$$\begin{matrix}Mathmematical Expression 15 & \\ {Δλ}_{cav} = \frac{Δ {n}_{eq , ring} ( {L}_{p , 1} + {L}_{p , 2} + {L}_{ring} / 2 )}{\begin{matrix}{n}_{g , a} {L}_{a} + {n}_{g , p , 1} {L}_{p , 1} + {n}_{g , p , 2} {L}_{p , 2} + \\ {n}_{g , Φ} {L}_{Φ} + {n}_{g , DBR , 1} {L}_{eff , DBR , 1} + \\ {n}_{g , DBR , 2} {L}_{eff , DBR , 2} + {n}_{g , ring} {L}_{ring} / 2\end{matrix}} λ & ( 14 )\end{matrix}$$

Accordingly, the ratio L_{ring,A}/L_{ring} in the refractive index modulation region of the MRR is appropriately adjusted, so that Δλ_{MRR}=Δλ_{cav}, which is the condition for a perfect match between the two shift amounts, or Expression (15), is satisfied.

$$\begin{matrix}Mathematical Expression 16 & \\ \frac{{L}_{ring , A}}{{n}_{g , ring} {L}_{ring}} = \frac{{L}_{p , 1} + {L}_{p , 2} + {L}_{ring} / 2}{\begin{matrix}{n}_{g , a} {L}_{a} + {n}_{g , p , 1} {L}_{p , 1} + {n}_{g , p , 2} {L}_{p , 2} + \\ \begin{matrix}{n}_{g , Φ} {L}_{} + {n}_{g , DBR , 1} {L}_{eff , DBR , 1} + \\ {n}_{g , DBR , 2} {L}_{eff , DBR , 2} + {n}_{g , ring} {L}_{ring} / 2\end{matrix}\end{matrix}} & ( 15 )\end{matrix}$$

Here, it should be noted that the refractive index modulation amount Δn_{eq,phase} of the phase adjustment region is fixed, and this condition for a perfect match is automatically satisfied when only the electrode for the MRR is swept.

Characteristics of Wavelength-Tunable Laser

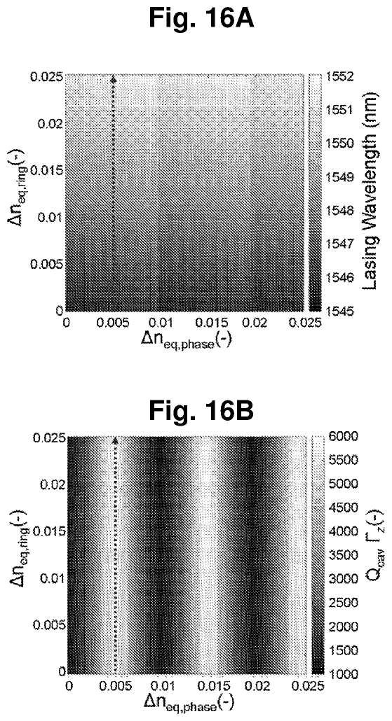

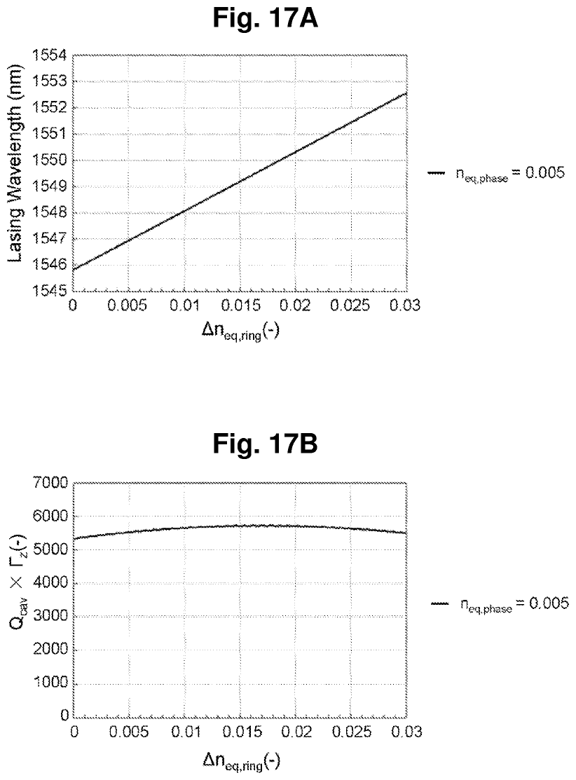

As an example of the characteristics of the wavelength-tunable laser 60 according to this embodiment, FIGS. 16A and 16B illustrate lasing wavelength and Q_{cav}Γ_{z} plotted as a function with two variables Δn_{eq,phase} and Δn_{eq, ring}. Here, the dashed arrows in the graphs indicate the wavelength sweep. Further, FIGS. 17A and 17B illustrate lasing wavelength and Q_{cav}Γ_{z} plotted as a function of Δn_{eq,ring} while Δn_{eq,phase} is fixed.

Table 4 shows various device parameters used to calculate the characteristics.

TABLE 4

| Parameter | Value | |
|---|---|---|
| Lₐ | 50 | μm |
| L_{p, 1} | 70 | μm |
| L_{p, 2} | 70 | μm |
| L_{ϕ} | 80 | μm |
| L_{ring, 1}/L_{ring} | 0.53 | |
| L_{DBR, 1} | 15 | μm |
| L_{DBR, 2} | 50 | μm |
| κ₁ | 1000 | cm⁻¹ |
| κ₂ | 1000 | cm⁻¹ |

As can be seen from FIGS. 16A to 17B, in the wavelength-tunable laser 60, Δn_{eq,ring} is swept while the value of Δn_{eq,phase} is fixed, and thus, the lasing wavelength changes in a fully mode-hop-free manner without any great change in the value of Q_{cav}Γ_{z}.

The shift amount is given by Expression (12), and linearly shifts with respect to the refractive index modulation amount of the MRR region. Here, Δn_{eq,phase} may be set to any desired value. However, to maximize Q_{cav}Γ_{z} and minimize the lasing threshold, it is desirable to set a longitudinal-mode resonance wavelength that matches the resonance wavelength of the MRR.

If the longitudinal-mode phase when Δn_{eq,phase}=0 is random at this point, to satisfy this condition for a match in all cases, it is necessary to satisfy Expression (10) and secure a phase adjustment amount of 2π at the maximum. Therefore, the operation mode of the wavelength-tunable laser 60 is as described below.

1. The detuning between the longitudinal-mode resonance wavelength and the resonance wavelength of the MRR when Δn_{eq,phase}=Δn_{eq, ring}=0 is measured, and is multiplied by a phase adjustment Δn_{eq,phase}=Δn_(eq, phase, 0) so as to compensate for the detuning and match both values with each other.

2. After the phase adjustment amount is fixed to Δn_{eq,phase}=Δn_{eq,ring, 0}, the value of Δn_{eq, ring} is set on the basis of Expression (16), to obtain a desired lasing wavelength λ_{lasing}.

$$\begin{matrix}Mathematical Expression 17 & \\ {λ}_{lasing} ( Δ {n}_{eq , ring} ) = {λ}_{lasing , 0} + \frac{{L}_{ring , A}}{{L}_{ring}} \frac{Δ {n}_{eq , ring}}{{n}_{g , ring}} {λ}_{lasing , 0} & ( 16 )\end{matrix}$$

Here, λ_{lasing,0} represents the lasing wavelength when Δn_{eq,phase}=Δn_{eq,ring,0}, and Δn_{eq,ring}=0. In a case where the condition for a perfect match shown in Expression (14) is satisfied, the lasing wavelength can be linearly tuned in a fully mode hop-free manner as shown in Expression (15). This is desirable for ease of control.

Here, Q_{cav}Γ_{z} always has a maximum value corresponding to the resonance peak of the MRR, and characteristics that excel in low lasing threshold properties and single-mode characteristics can be achieved.

Effects

With the three-electrode configuration in the wavelength-tunable laser 60 according to this embodiment, the effects described below can be achieved.

1. Once the phase offset adjustment is performed to compensate for the detuning between the longitudinal mode and the MRR when the refractive indexes are not modulated, the phase adjustment amount thereafter may be fixed at that value, and lasing wavelength tunability is achieved simply by sweeping the single electrode for the MRR. This is a very easy method for controlling a three-electrode configuration.

2. The lasing wavelength becomes completely mode-hop-free, and can be linearly tuned with respect to the refractive index modulation amount.

3. The longitudinal mode and the MRR always have the same resonance wavelength, and characteristics that excel in low lasing threshold properties and single-mode characteristics can be achieved over the entire tuning range.

### Fifth Embodiment

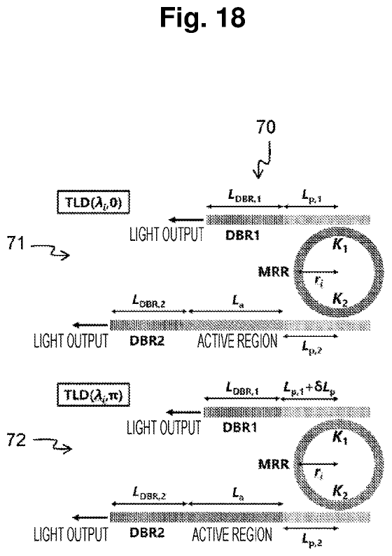

A wavelength-tunable laser according to a fifth embodiment of the present invention is now described with reference to FIGS. 18 to 20.

In the first to fourth embodiments, examples in which a single wavelength-tunable laser (MRR-DBR-TLD) is used have been described. However, in an actual use mode, a plurality of MRR-DBR-TLDs having different lasing wavelengths is turned into an array, so that the array can be used as a transmitter for WDM transmission, and can be used as a wavelength-tunable light source that continuously covers a wide wavelength region.

Here, to systematically change the wavelength region to be covered by each MRR-DBR-TLD, the radius of each MRR should be set on the basis of Expression (17).

$$\begin{matrix}Mathematical Expression 18 & \\ {λ}_{MRR , i} = \frac{2 π {n}_{eq , ring}}{m} {r}_{i} & ( 17 )\end{matrix}$$

Here, λ_{MRR,i} represents the resonance wavelength of the MRR in the ith MRR-DBR-TLD,m represents the appropriate resonance mode order corresponding to a desired resonance wavelength, and ri represents the radius of the MRR in the ith MRR-DBR-TLD.

According to Expression (17), in a case where the lasing wavelengths of the respective MRR-DBR-TLDs are arranged in a wavelength grid at equal intervals, for example, the radii of the respective MRRs should be set at equal intervals.

In a case where a resonator structure of a type that does not involve phase adjustment is used as in wavelength-tunable lasers according to the first embodiment and the second embodiment (FIGS. 1 and 8), the presence of a mode hopping region might be a problem. That is, since the wavelength region corresponding to a mode hopping region exists as a local gap in the wavelength region of each wavelength-tunable laser, it might be impossible to continuously cover the entire target wavelength region without a gap.

A wavelength-tunable laser 70 according to this embodiment can solve the above-mentioned problem regarding a mode hopping region, and continuously cover the entire target wavelength region without a gap.

Configuration of a Wavelength-Tunable Laser

As illustrated in FIG. 18, the wavelength-tunable laser 70 includes two MRR-DBR-TLDs 71 and 72. The MRR-DBR-TLDs 71 and 72 have substantially the same configuration as the wavelength-tunable laser 10 according to the first embodiment, but the first waveguides thereof have different lengths. The length of the first waveguide of the MRR-DBR-TLD 72 is longer than the length of the first waveguide of the MRR-DBR-TLD 71 by δLₚ=λᵢ/(4n_{eq,p}). The structural parameters for the first waveguides in the MRR-DBR-TLDs 71 and 72 are all the same.

This length difference δLₚ corresponds to a phase difference π, when converted into a longitudinal-mode phase. Therefore, a short TLD is referred to as “TLD(λ_{i,o})”, and a long TLD is referred to as “TLD(λ_{i,π})”.

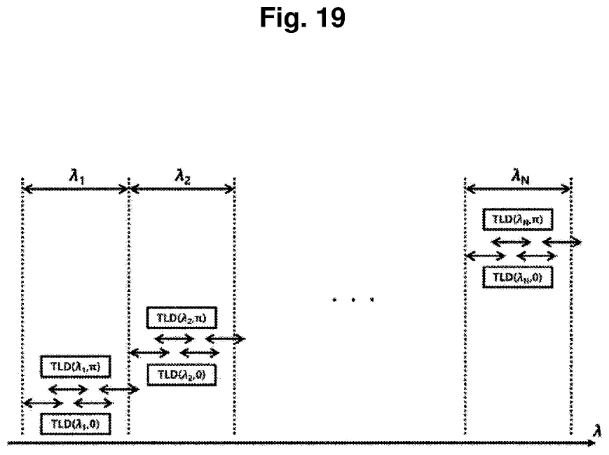

At this point of time, the longitudinal-mode phases are different from each other by π. Therefore, hop-free wavelength regions and the mode hopping regions are alternately set in the wavelength characteristics as illustrated in FIG. 19.

In FIG. 19, in the respective wavelength regions from λ₁ to λ_{N}, TLD(λ_{i,o}) and TLD(λ_{i,π}) are alternately shown as hop-free wavelength regions (double-headed arrows in the drawing).

As two TLDs having different longitudinal-mode phases by π in each wavelength region are included as above, it is possible to continuously cover the entire wavelength region from λᵢ to λ_{N} without a gap, not using a phase adjustment electrode.

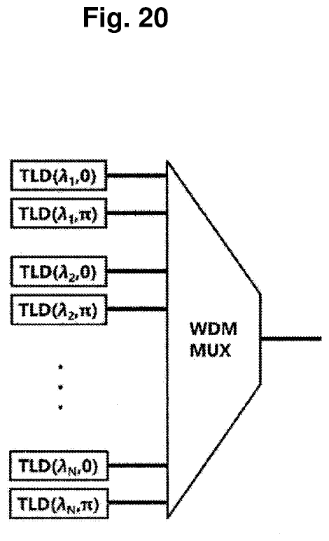

In the above configuration, two MRR-DBR-TLDs are used. However, if a plurality of MRR-DBR-TLDs is used, wavelength tuning in an even wider region becomes possible. FIG. 20 illustrates an example configuration of a wavelength-tunable laser in which a plurality (N) of MRR-DBR-TLDs is connected to a MUX circuit of WDM.

A wavelength-tunable laser having this configuration can be made to operate as a wide continuous wavelength-tunable light source capable of outputting light having a desired wavelength in the entire wavelength region.

In the example described in this embodiment, a configuration based on the wavelength-tunable laser according to the first embodiment is used for each MRR-DBR-TLD. However, a configuration based on a wavelength-tunable laser according to any other embodiment maybe used for each MRR-DBR-TLD.

Effects

With the wavelength-tunable laser 70 according to this embodiment, the effects described below can be achieved.

1. As two MRR-DBR-TLDs are included, the mode hopping regions can be covered without phase adjustment, and it is possible to achieve both ease of control and continuous lasing wavelength tunability.

2. With a WDM configuration including a plurality of MRR-DBR-TLDs, it is possible to continuously cover a very wide wavelength region such as the entire C-band. In this case, phase adjustment in each MRR-DBR-TLD is unnecessary. Thus, a wide WDM light source that excels in controllability and low power consumption can be achieved.

In the examples described in the embodiments of the present invention, the two waveguides coupled to a MRR are parallel. However, embodiments are not limited to this, and the two waveguides coupled to a MRR may not be parallel.

The embodiments of the present invention show examples of the structures, dimensions, materials, and the like of the respective components in the configuration, manufacturing method, and the like regarding wavelength-tunable lasers, but the present invention is not limited thereto. A wavelength-tunable laser is only required to exhibit its functions and achieve its effects.

### INDUSTRIAL APPLICABILITY

The present invention can be applied to a wavelength-division-multiplexing optical transmission system, and photonic devices that are used in the system.

### REFERENCE SIGNS LIST

10 wavelength-tunable laser
101 first reflection region (first DBR)
102 first coupled waveguide
103 circling waveguide (MRR)
104 second coupled waveguide
105 active region
106 second reflection region (second DBR)

1-8. (canceled)

9. A wavelength-tunable laser comprising:
a circling waveguide having a circling structure;
a first coupled waveguide coupled to the circling waveguide in a first region; and
a second coupled waveguide coupled to the circling waveguide in a second region,
wherein a first reflection region is connected in a light guiding direction of the first coupled waveguide,
wherein an active region and a second reflection region are sequentially connected in a light guiding direction of the second coupled waveguide, and
wherein a refractive index of at least part of the circling waveguide is modulated.

10. The wavelength-tunable laser according to claim 9, wherein a refractive index of at least part of a region in which light is guided in the first coupled waveguide and a refractive index of at least part of a region in which light is guided in the second coupled waveguide are modulated at substantially the same time as the refractive index of the at least part of the circling waveguide.

11. The wavelength-tunable laser according to claim 9, wherein:
a refractive index of at least part of a region in which light is guided in the first coupled waveguide and a refractive index of at least part of a region in which light is guided in the second coupled waveguide are modulated with substantially identical signals; and
a refractive index of the circling waveguide is modulated with a different signal from the substantially identical signals.

12. The wavelength-tunable laser according to claim 11, wherein only a resonance wavelength shift amount of the circling waveguide is modulated so that a longitudinal-mode phase adjustment amount is switched between two values that are 0 and π.

13. The wavelength-tunable laser according to claim 9, wherein:
a refractive index of part of a region in which light is guided in the first coupled waveguide and a refractive index of at least part of a region in which light is guided in the second coupled waveguide are modulated with signals substantially identical to a signal for a refractive index of part of the circling waveguide;
a refractive index of a portion other than the part of the region in which light is guided in the first coupled waveguide is modulated with a different signal from the substantially identical signals; and
a resonance wavelength shift amount of the circling waveguide is equal to a longitudinal-mode resonance wavelength shift amount.

14. A wavelength-tunable laser comprising N wavelength-tunable lasers of claim 9.

15. The wavelength-tunable laser according to claim 9, wherein the wavelength-tunable laser has a membrane structure.

16. A wavelength-tunable laser comprising:
a circling waveguide;
a Y-branched coupled waveguide; and
an active region and a reflection region sequentially provided in a light guiding direction at a base end of the Y-branched coupled waveguide,
wherein a first coupled waveguide of the Y-branched coupled waveguide is coupled to the circling waveguide in a first region,
wherein a second coupled waveguide of the Y-branched coupled waveguide is coupled to the circling waveguide in a second region, and
a refractive index of at least part of the circling waveguide is modulated.

17. The wavelength-tunable laser according to claim 16, wherein a refractive index of at least part of a region in which light is guided in the first coupled waveguide, and a refractive index of at least part of a region in which light is guided in the second coupled waveguide are modulated at substantially the same time as the refractive index of at least part of the circling waveguide.

18. The wavelength-tunable laser according to claim 16, wherein a refractive index of at least part of a region in which light is guided in the first coupled waveguide and a refractive index of at least part of a region in which light is guided in the second coupled waveguide are modulated at substantially the same time as the refractive index of the at least part of the circling waveguide.

19. The wavelength-tunable laser according to claim 16, wherein:
a refractive index of at least part of a region in which light is guided in the first coupled waveguide and a refractive index of at least part of a region in which light is guided in the second coupled waveguide are modulated with substantially identical signals; and
a refractive index of the circling waveguide is modulated with a different signal from the substantially identical signals.

20. The wavelength-tunable laser according to claim 19, wherein only a resonance wavelength shift amount of the circling waveguide is modulated so that a longitudinal-mode phase adjustment amount is switched between two values that are 0 and π.

21. The wavelength-tunable laser according to claim 19, wherein:
a refractive index of part of a region in which light is guided in the first coupled waveguide and a refractive index of at least part of a region in which light is guided in the second coupled waveguide are modulated with signals substantially identical to a signal for a refractive index of part of the circling waveguide;
a refractive index of a portion other than the part of the region in which light is guided in the first coupled waveguide is modulated with a different signal from the substantially identical signals; and
a resonance wavelength shift amount of the circling waveguide is equal to a longitudinal-mode resonance wavelength shift amount.

22. A wavelength-tunable laser comprising N wavelength-tunable lasers of claim 16.

23. The wavelength-tunable laser according to claim 16, wherein the wavelength-tunable laser has a membrane structure.
